(19) United States
(12) Patent Application Publication
(10) Pub. No.: US 2026/0164646 A1
(43) Pub. Date: Jun. 11, 2026

(54) ACCESS LINE STRUCTURE FOR A SEMICONDUCTOR DEVICE

(71) Applicant: Micron Technology, Inc., Boise, ID (US)

(72) Inventor: Yuichi Yokoyama, Boise, ID (US)

(21) Appl. No.: 19/179,525

(22) Filed: Apr. 15, 2025

Related U.S. Application Data
(60) Provisional application No. 63/653,443, filed on May 30, 2024.

(51) Int. Cl. H10B 12/00; H10D 1/68; H10D 62/83

(52) U.S. Cl. CPC H10B 12/488; H10B 12/05; H10D 1/714; H10D 62/83; H10B 12/03; H10B 12/50

(57) ABSTRACT

Systems, methods, and apparatus are provided for access line structures for a semiconductor device. Access line structures can be formed by forming alternating layers of silicon germanium and silicon materials to define a vertical stack and forming first vertical openings through the vertical stack to define elongated vertical columns of the alternating layers, wherein one of the plurality of first vertical openings is formed to a second width that is different than a first width of other first vertical openings. The method further includes filling the plurality of first vertical openings with a first dielectric material, forming a second vertical opening through the vertical stack, and selectively etching the silicon germanium layers to form horizontal openings. The method further includes forming access lines in the horizontal openings, wherein the access lines are formed in an array portion of the memory cells but are separated from a redundant portion of the memory cells.

### PRIORITY INFORMATION

This application claims the benefit of U.S. Provisional Application Number 63/653,443, filed on May 30, 2024, the contents of which are incorporated herein by reference.

### TECHNICAL FIELD

The present disclosure relates generally to memory devices, and more particularly, to an access line structure for a semiconductor device.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, coupled by the access device to a sense line, such as a digit line. The access device can be activated (e.g., to select the cell) by an access line coupled to the access device. The capacitor can store a charge corresponding to a data value of a respective memory cell (e.g., a logic “1” or “0”).

### BRIEF DESCRIPTION OF THE DRAWINGS

FIG. 1A is a schematic illustration of an array of memory cells in a vertical three dimensional (3D) memory, in accordance with a number of embodiments of the present disclosure.

FIG. 1B is a perspective view illustrating a portion of a three dimensional (3D) semiconductor memory device, in accordance with a number of embodiments of the present disclosure.

FIG. 2 illustrates a portion of a horizontal access devices in vertical three dimensional (3D) memory, in accordance with a number of embodiments of the present disclosure.

FIG. 3 is a perspective view illustrating horizontal access devices, in accordance with a number of embodiments of the present disclosure.

FIG. 4 is a cross-sectional view of a vertical stack in vertical three dimensional (3D) memory, in accordance with a number of embodiments of the present disclosure.

FIGS. 5A to 5B illustrate an example method at one stage of a semiconductor fabrication process for forming an access line structure for a memory device, in accordance with a number of embodiments of the present disclosure.

FIGS. 6A to 6D illustrate an example method at one stage of a semiconductor fabrication process for forming an access line structure for a memory device, in accordance with a number of embodiments of the present disclosure.

FIGS. 7A to 7B illustrate an example method at another stage of a semiconductor fabrication process for forming an access line structure for a memory device, in accordance with a number of embodiments of the present disclosure.

FIG. 8 illustrates an example method at another stage of a semiconductor fabrication process for forming an access line structure for a memory device, in accordance with a number of embodiments of the present disclosure.

FIG. 9 illustrates an example method at another stage of a semiconductor fabrication process for forming an access line structure for a memory device, in accordance with a number of embodiments of the present disclosure.

FIG. 10A illustrates a top-down view of an access line structure for a memory device, in accordance with a number of embodiments of the present disclosure.

FIG. 10B illustrates a side view of an array of memory cells below an access line structure for a memory device, in accordance with a number of embodiments of the present disclosure.

FIG. 11 is a block diagram of an apparatus in the form of a computing system including a memory device in accordance with a number of embodiments of the present disclosure.

### DETAILED DESCRIPTION

Embodiments of the present disclosure describe forming an access line structure for a memory device. A vertically oriented sense line (e.g., digit line) is formed with horizontally oriented access devices and horizontally oriented access lines (e.g., word lines) in an array of vertically stacked memory cells. The horizontally oriented access devices are integrated with horizontally oriented access lines having first source/drain regions and second source/drain regions separated by channel regions and integrated with vertically oriented digit lines. The array of vertically stacked memory cells can include active memory cells that are coupled to redundant memory cells, wherein the active memory cells and the redundant memory cells are coupled to an access line. As used herein, the term “active memory cells” refers to memory cells that correspond to addresses in a memory array. As used herein, the term “redundant memory cells” refers to memory cells that are used to replace active memory cells when one or more active memory cells fail.

When active memory cells of a horizontally oriented access line are coupled to redundant memory cells of the same horizontally oriented access line, the active memory cells and redundant memory cells can both be activated when the horizontally oriented access line is activated. As used herein, the term, “activated” refers to supplying a memory device component and or a conductive line (e.g., an access line or a sense line) with a current and/or voltage. Since redundant memory cells are not intended to be activated when corresponding active memory cells are activated and functioning as intended, activating both an active memory cell and a corresponding redundant memory cell can be detrimental to a memory device in multiple ways including, but not limited to, causing a short circuit in the memory device.

However, embodiments of the present disclosure can separate the active memory cells from the redundant memory cells by separating active access lines from redundant access lines. As used herein, the term “active access line” refers to a portion of an access line to which active memory cells are coupled and the term, “redundant access line” refers to a portion of an access line to which redundant memory cells are coupled. Active access lines can be separated from redundant access lines by forming one or more of the vertical openings used to define elongated vertical columns of the alternating layers to have a greater width than the remaining vertical openings used to define elongated, vertical pillar columns. As used herein, terms “form” and “define” can be used interchangeably. A horizontally oriented access line that passes through one of the vertical openings with the increased width may not couple to an access line on an opposite side of the vertical opening with the increased width due to the distance. Further, memory cells on opposing sides of that same vertical opening with the increased width in a horizontal direction will be separated due to the distance created by the increased width of the vertical opening.

Forming one or more of the vertical openings to be wider than the remaining vertical openings allows for active access lines to be formed separate from redundant access lines and active memory cells to be formed separate from redundant memory cells. This improves over previous approaches because this allows the active access lines and active memory cells to be separated from the redundant access lines and redundant memory cells, respectively, without performing additional processing on other parts of the memory array.

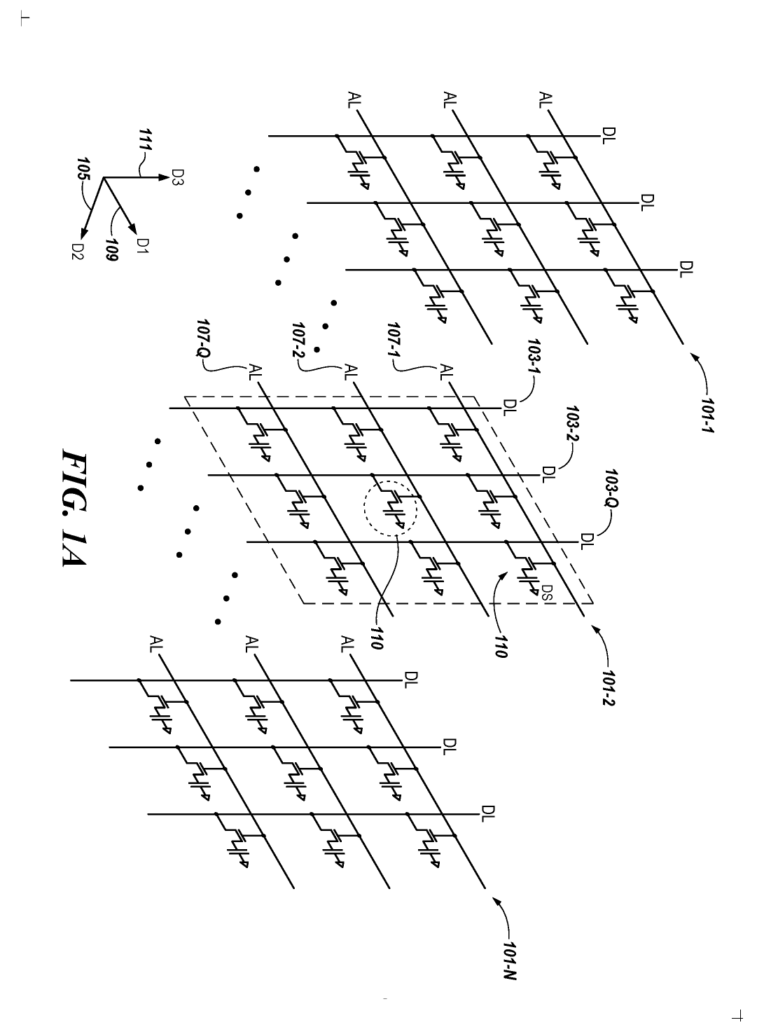

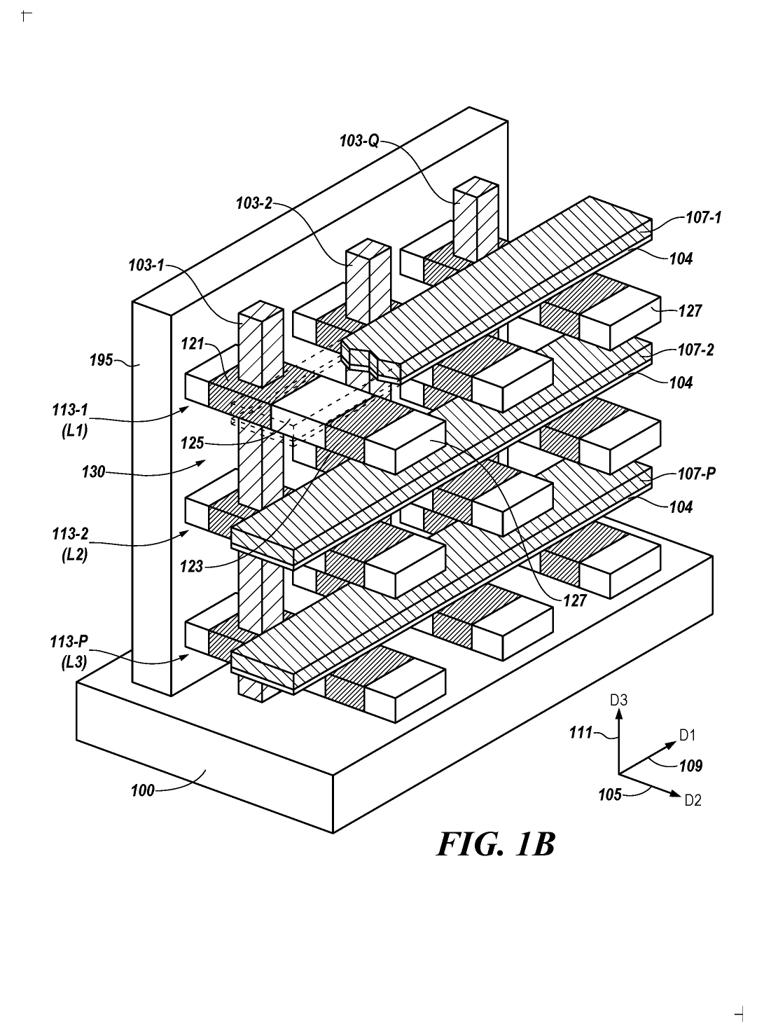

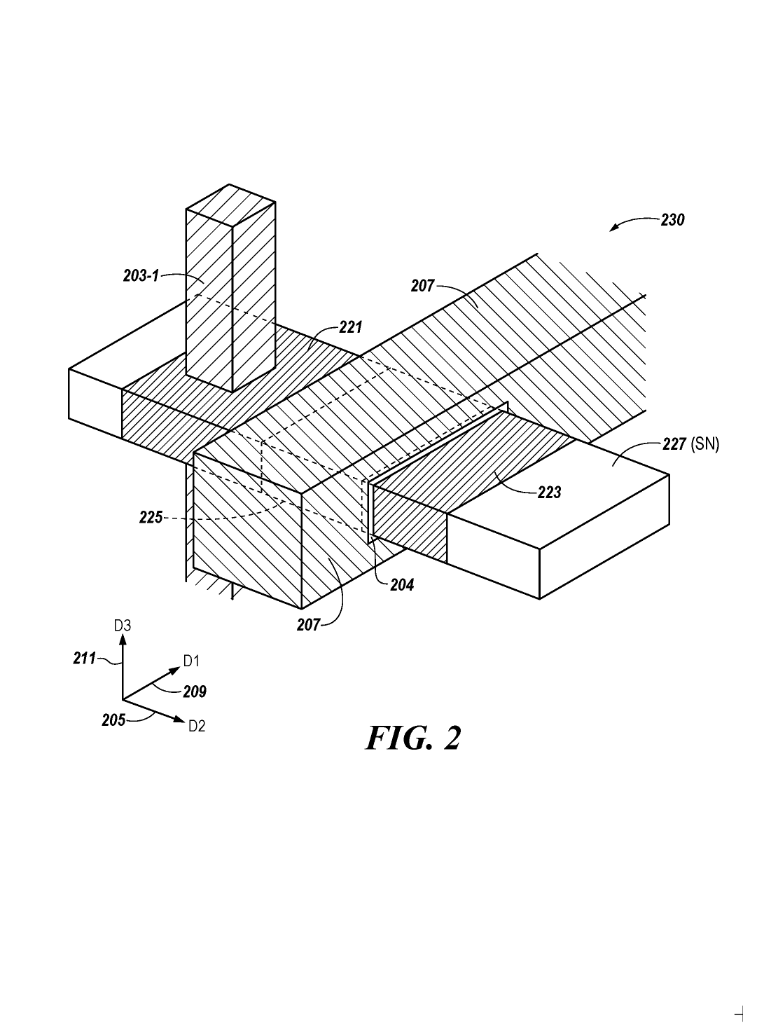

The figures herein follow a numbering convention in which the first digit or digits correspond to the figure number of the drawing and the remaining digits identify an element or component in the drawing. Similar elements or components between different figures may be identified by the use of similar digits. For example, reference numeral 103 may reference element “03” in FIG. 1A, and a similar element may be referenced as 203 in FIG. 2. Multiple analogous elements within one figure may be referenced with a reference numeral followed by a hyphen and another numeral or a letter. For example, 107-1 may reference element 107-1 in FIG. 1A and 107-2 may reference element 107-2, which may be analogous to element 107-1. Such analogous elements may be generally referenced without the hyphen and extra numeral or letter. For example, elements 107-1 and 107-2 or other analogous elements may be generally referenced as 107.

FIG. 1A is a schematic illustration of an array of memory cells in a vertical three dimensional (3D) memory in accordance with a number of embodiments of the present disclosure. FIG. 1A illustrates that a cell array may have a plurality of sub cell arrays 101-1, 101-2, . . ., 101-N. The sub cell arrays 101-1, 101-2, . . ., 101-N may be arranged along a second direction (D2) 105. Each of the sub cell arrays, e.g., sub cell array 101-2, may include a plurality of access lines 107-1, 107-2, . . ., 107-Q (which also may be referred to a word lines). Also, each of the sub cell arrays, e.g., sub cell array 101-2, may include a plurality of digit lines 103-1, 103-2, . . ., 103-Q (which also may be referred to as bit lines, data lines, or sense lines). In FIG. 1A, the access lines 107-1, 107-2, . . ., 107-Q are illustrated extending in a first direction (D1) 109 and the digit lines 103-1, 103-2, . . ., 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . ., 103-Q are extending in a vertical direction, e.g., third direction (D3) 111.

A memory cell, e.g., 110, may include an access device, e.g., access transistor, and a storage node located at an intersection of each access line 107-1, 107-2, . . ., 107-Q and each digit line 103-1, 103-2, . . ., 103-Q. Memory cells may be written to, or read from, using the access lines 107-1, 107-2, . . ., 107-Q and digit lines 103-1, 103-2, . . ., 103-Q. The access lines 107-1, 107-2, . . ., 107-Q may conductively interconnect memory cells along horizontal rows of each sub cell array 101-, 101-2, . . ., 101-N, and the digit lines 103-1, 103-2, . . ., 103-Q may conductively interconnect memory cells along vertical columns of each sub cell array 101-1, 101-2, . . ., 101-N. One memory cell, e.g., 110, may be located between one access line, e.g., 107-2, and one digit line, e.g., 103-2. Each memory cell may be uniquely addressed through a combination of an access line 107-1, 107-2, . . ., 107-Q and a digit line 103-1, 103-2, . . ., 103-Q.

The access lines 107-1, 107-2, . . ., 107-Q may be or include conducting patterns (e.g., metal lines) disposed on and spaced apart from a substrate. The access lines 107-1, 107-2, . . ., 107-Q may extend in a first direction (D1) 109. The access lines 107-1, 107-2, . . ., 107-Q in one sub cell array, e.g., 101-2, may be spaced apart from each other in a vertical direction, e.g., in a third direction (D3) 111.

The digit lines 103-1, 103-2, . . ., 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line (e.g., 107-2) and a first conductive node (e.g., a first source/drain region) of an access device (e.g., transistor) of the memory cell 110 may be connected to a digit line (e.g., 103-2). Each of the memory cells (e.g., memory cell 110) may be connected to a storage node (e.g., capacitor). A second conductive node (e.g., second source/drain region) of the access device (e.g., transistor) of the memory cell 110 may be connected to the storage node (e.g., capacitor). While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line (e.g., 103-2) and the other may be connected to a storage node.

FIG. 1B illustrates a perspective view showing a three dimensional (3D) semiconductor memory device (e.g., a portion of a sub cell array 101-2 shown in FIG. 1A as a vertically oriented stack of memory cells in an array) according to some embodiments of the present disclosure.

As shown in FIG. 1B, a substrate 100 may have formed thereon one of the plurality of sub cell arrays (e.g., 101-2) described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells (e.g., memory cell 110 in FIG. 1A) extending in a vertical direction (e.g., third direction (D3) 111). According to some embodiments, the vertically oriented stack of memory cells may be fabricated such that each memory cell (e.g., memory cell 110 in FIG. 1A) is formed on plurality of vertical levels (e.g., a first level (L1), a second level (L2), and a third level (L3)). The repeating, vertical levels, L1, L2, and L3, may be arranged (e.g., “stacked”) a vertical direction (e.g., third direction (D3) 111 shown in FIG. 1A) and may be separated from the substrate 100 by an insulator material. Each of the repeating, vertical levels, L1, L2, and L3 may include a plurality of discrete components (e.g., regions) to the horizontally oriented access devices 130 (e.g., transistors), and storage nodes (e.g., capacitors) including access line 107-1, 107-2, . . ., 107-Q connections and digit line 103-1, 103-2, . . ., 103-Q connections. The plurality of discrete components to the horizontally oriented access devices 130 (e.g., transistors) may be formed in a plurality of iterations of vertically, repeating layers within each level and may extend horizontally in the second direction (D2) 105, analogous to second direction (D2) 105 shown in FIG. 1A.

The plurality of discrete components to the laterally oriented access devices 130 (e.g., transistors) may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127 (e.g., capacitor) may be connected to one respective end of the access device. As shown in FIG. 1B, the storage node 127 may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell (e.g., memory cell 110 in FIG. 1A) may similarly extend in the second direction (D2) 105, analogous to second direction (D2) 105 shown in FIG. 1A.

As shown in FIG. 1B a plurality of horizontally oriented access lines 107-1, 107-2, . . ., 107-Q extend in the first direction (D1) 109, analogous to the first direction (D1) 109 in FIG. 1A. The plurality of horizontally oriented access lines 107-1, 107-2, . . ., 107-Q may be analogous to the access lines 107-1, 107-2, . . ., 107-Q shown in FIG. 1A. The plurality of horizontally oriented access lines 107-1, 107-2, . . ., 107-Q may be arranged (e.g., “stacked”) along the third direction (D3) 111. The plurality of horizontally oriented access lines 107-1, 107-2, . . ., 107-Q may include a conductive material. For example, the conductive material may include one or more of a doped semiconductor (e.g., doped silicon, doped germanium, etc.), a conductive metal nitride (e.g., titanium nitride, tantalum nitride, etc.), a metal (e.g., tungsten (W), titanium (Ti), tantalum (Ta), ruthenium (Ru), cobalt (Co), molybdenum (Mo), etc.), and/or a metal-semiconductor compound (e.g., tungsten silicide, cobalt silicide, titanium silicide, etc.). Embodiments, however, are not limited to these examples.

Among each of the vertical levels, (L1) 113-1, (L2) 113-2, and (L3) 113-P, the horizontally oriented memory cells (e.g., memory cell 110 in FIG. 1A) may be spaced apart from one another horizontally in the first direction (D1) 109. However, the plurality of discrete components to the horizontally oriented access devices 130 (e.g., first source/drain region 121 and second source/drain region 123 separated by a channel region 125), extending laterally in the second direction (D2) 105, and the plurality of horizontally oriented access lines 107-1, 107-2, . . ., 107-Q extending laterally in the first direction (D1) 109, may be formed within different vertical layers within each level. For example, the plurality of horizontally oriented access lines 107-1, 107-2, . . ., 107-Q, extending in the first direction (D1) 109, may be formed on a top surface opposing and electrically coupled to the channel regions 125, separated therefrom by a gate dielectric, and orthogonal to horizontally oriented access devices 130 extending in laterally in the second direction (D2) 105. In some embodiments, the plurality of horizontally oriented access lines 107-1, 107-2, . . ., 107-Q, extending in the first direction (D1) 109 are formed in a higher vertical layer, farther from the substrate 100, within a level (e.g., within level (L1)), than a layer in which the discrete components (e.g., first source/drain region 121 and second source/drain region 123 separated by a channel region 125), of the horizontally oriented access device are formed.

As shown in the example embodiment of FIG. 1B, the digit lines, 103-1, 103-2, . . ., 103-Q, extend in a vertical direction with respect to the substrate 100 (e.g., in a third direction (D3) 111). Further, as shown in FIG. 1B, the digit lines, 103-1, 103-2, . . ., 103-Q, in one sub cell array (e.g., sub cell array 101-2 in FIG. 1A) may be spaced apart from each other in the first direction (D1) 109. The digit lines, 103-1, 103-2, . . ., 103-Q, may be provided, extending vertically relative to the substrate 100 in the third direction (D3) 111 in vertical alignment with source/drain regions to serve as first source/drain regions 121 or, be vertically adjacent first source/drain regions 121 for each of the horizontally oriented access devices 130 extending laterally in the second direction (D2) 105, but adjacent to each other on a level (e.g., first level (L1)) in the first direction (D1) 109. Each of the digit lines, 103-1, 103-2, . . ., 103-Q, may vertically extend, in the third direction (D3), on sidewalls adjacent first source/drain regions 121 of respective ones of the plurality of horizontally oriented access devices 130 that are vertically stacked. In some embodiments, the plurality of vertically oriented digit lines 103-1, 103-2, . . ., 103-Q, extending in the third direction (D3) 111, may be connected to side surfaces of the first source/drain regions 121 directly and/or through additional contacts including metal silicides.

For example, a first one of the vertically extending digit lines (e.g., 103-1) may be adjacent a sidewall of a first source/drain region 121 to a first one of the horizontally oriented access devices 130 in the first level (L1) 113-1, a sidewall of a first source/drain region 121 of a first one of the horizontally oriented access devices 130 in the second level (L2) 113-2, and a sidewall of a first source/drain region 121 of a first one of the horizontally oriented access devices 130 in the third level (L3) 113-P, etc. Similarly, a second one of the vertically extending digit lines (e.g., 103-2) may be adjacent a sidewall to a first source/drain region 121 of a second one of the horizontally oriented access devices 130 in the first level (L1) 113-1, spaced apart from the first one of horizontally oriented access devices 130 in the first level (L1) 113-1 in the first direction (D1) 109. And the second one of the vertically extending digit lines (e.g., 103-2) may be adjacent a sidewall of a first source/drain region 121 of a second one of the laterally oriented access devices 130 in the second level (L2) 113-2, and a sidewall of a first source/drain region 121 of a second one of the horizontally oriented access devices 130 in the third level (L3) 113-P, etc. Embodiments are not limited to a particular number of levels.

The vertically extending digit lines, 103-1, 103-2, . . ., 103-Q, may include a conductive material, such as, for example, one of a doped semiconductor material, a conductive metal nitride, metal, and/or a metal-semiconductor compound. The digit lines, 103-1, 103-2, . . ., 103-Q, may correspond to digit lines (DL) described in connection with FIG. 1A.

As shown in the example embodiment of FIG. 1B, a conductive body contact 195 may be formed extending in the first direction (D1) 109 along an end surface of the horizontally oriented access devices 130 in each level (L1) 113-1, (L2) 113-2, and (L3) 113-P above the substrate 100. The body contact 195 may be connected to a body (e.g., body region) of the horizontally oriented access devices 130 in each memory cell. The body contact 195 may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell (e.g., memory cell 110 in FIG. 1) of the vertically stacked array of memory cells (e.g., within a sub cell array 101-2 in FIG. 1) according to some embodiments of the present disclosure. As shown in FIG. 2, the first and the second source/drain regions, 221 and 223, may be impurity doped regions to the laterally oriented access devices 230. The first and the second source/drain regions 221 and 223 may be separated by a channel 225 formed in a body of semiconductor material, e.g., body region of the horizontally oriented access devices 230. The first and the second source/drain regions, 221 and 223, may be formed from an n-type or p-type dopant doped in the body region. However, embodiments are not so limited.

For example, for an n-type conductivity transistor construction the body region of the laterally oriented access devices 230 may be formed of a low doped p-type (p-) semiconductor material. In one embodiment, the body region and the channel 225 separating the first and the second source/drain regions, 221 and 223, may include a low doped, p-type (e.g., low dopant concentration (p-)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230 may be of a p-type conductivity construction in which case the impurity (e.g., dopant) conductivity types would be reversed.

As shown in FIG. 2, the first and the second source/drain regions, 221 and 223, may be impurity doped regions to the laterally oriented access devices 230. The first and the second source/drain regions may be separated by a channel 225 formed in a body of semiconductor material (e.g., body region) of the horizontally oriented access devices 230. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented transistor 230 may have a body portion which is below the first source/drain region 221 and is in electrical contact with the body contact. Further, as shown in the example embodiment of FIG. 2, an access line (e.g., 207) analogous to the access lines 107-1, 107-2, . . ., 107-Q shown in FIG. 1, may disposed on a top surface opposing and coupled to a channel region 225, separated therefrom by a gate dielectric 204. The gate dielectric material 204 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 204 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line (e.g., 203-1) analogous to the digit lines 103-1, 103-2, . . ., 103-Q in FIG. 1, may be vertically extending in the third direction (D3) 211 adjacent a sidewall of the first source/drain region 221 in the body to the horizontally oriented access devices 230 horizontally conducting between the first and the second source/drain regions 221 and 223 along the second direction (D2) 205. In this embodiment, the vertically oriented digit line 203-1 is formed symmetrically, in vertical alignment, and in electrical contact with the first source/drain region 221. The digit line 203-1 may be formed in contact with an insulator material such that there is no body contact within channel 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 321 and is in contact with the body contact. An insulator material may fill the body contact such that the first source/drain region 221 may not be in electrical contact with channel 225. Further, as shown in the example embodiment of FIG. 2, an access line 207 analogous to the access lines 107-1, 107-2, . . ., 107-Q shown in FIG. 1, may be disposed all around and coupled to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

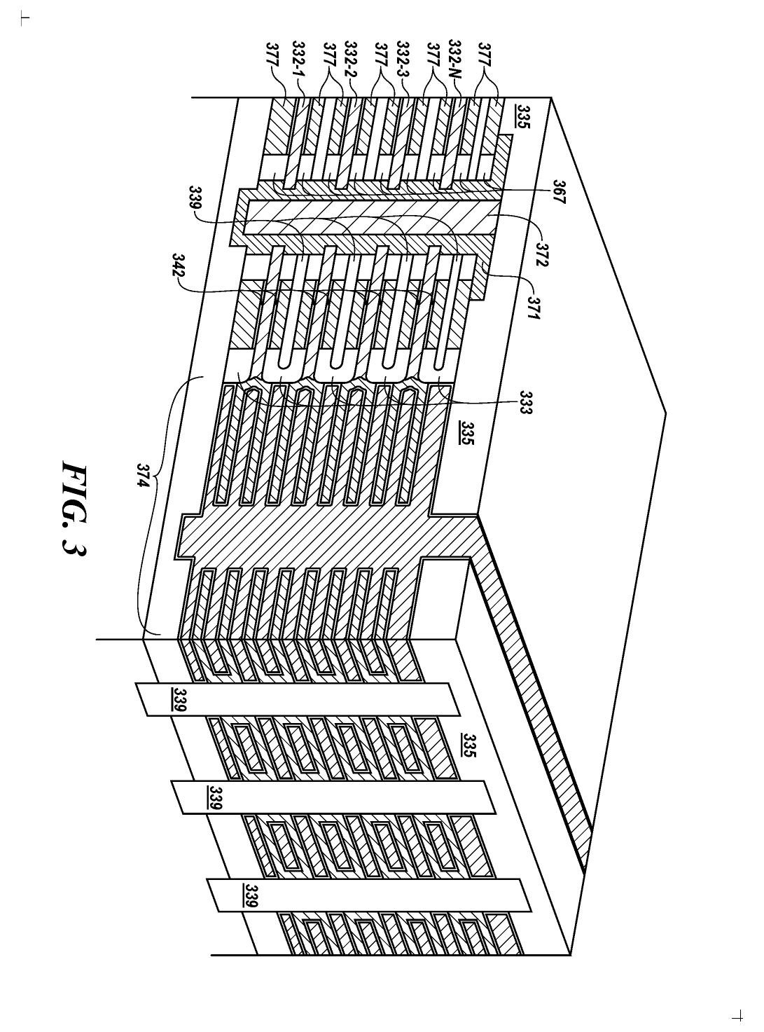

FIG. 3 is a perspective view illustrating horizontal access devices in accordance with a number of embodiments of the present disclosure. FIG. 3 includes first conductive material 377, a silicon (Si) material 332, a photolithographic mask material (e.g., mask material) 335, an interlayer dielectric (ILD) fill material 367, a second conductive material 370, a metal material 372, a first dielectric material 339, a second dielectric material 333, a second interlayer dielectric material 342, and a plurality of storage nodes (e.g., capacitors) 374.

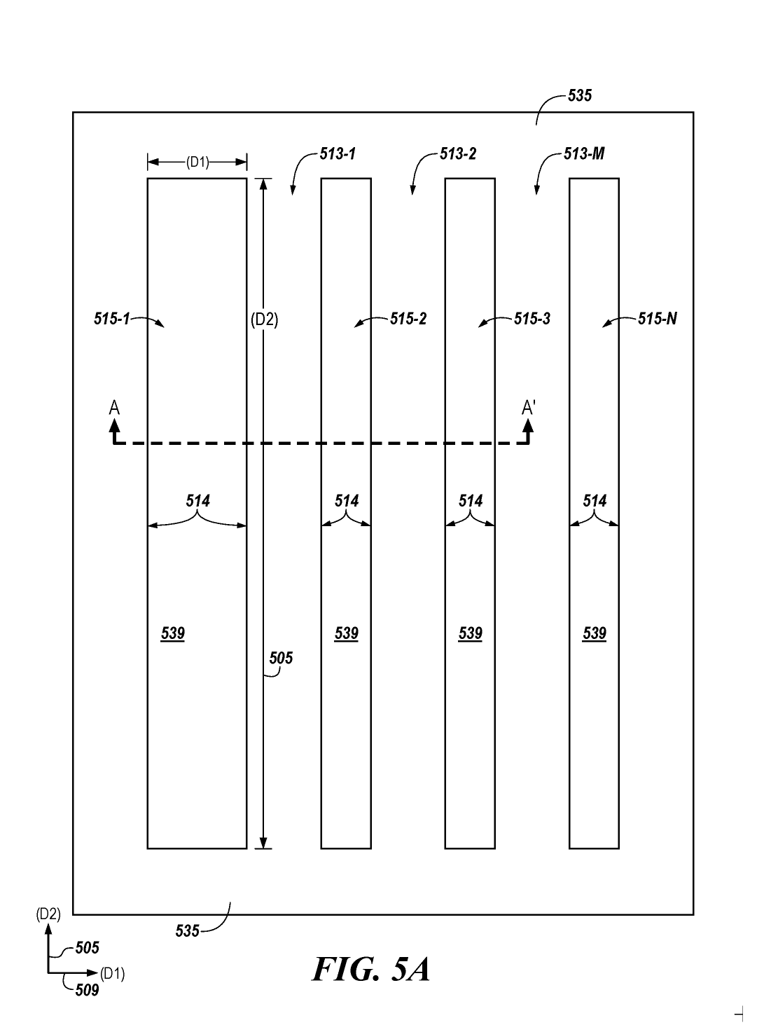

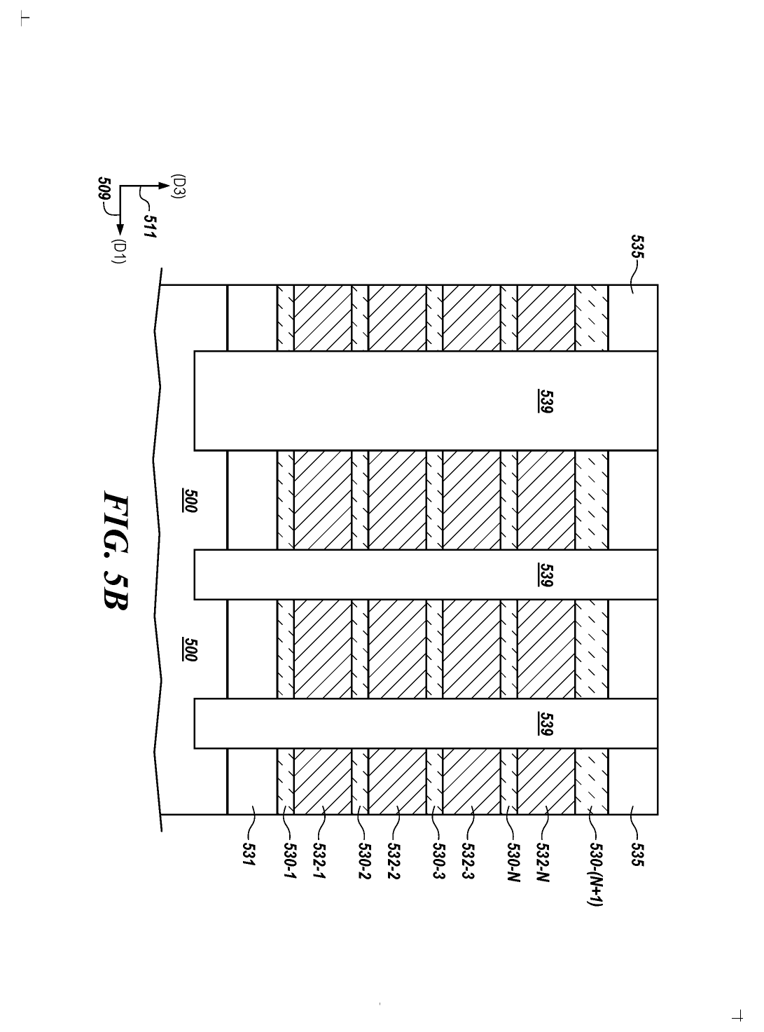

FIG. 3 illustrates a portion of a vertical 3D memory array that is formed in accordance with the process described in FIGS. 5-9 of this application. The horizontal access devices of the vertical 3D memory array can include the second dielectric material 333, the first conductive material 377, a first dielectric material 339, and ILD fill material 367. In some embodiments, the first dielectric material 339 can be formed using an oxide material. Further, in some embodiments, the first dielectric material 339 and the second dielectric material 333 can be formed from the same material. In other embodiments, a first material can be used to form the first dielectric material 339 and a second material can be used to form the second dielectric material 333, wherein the first material is a different material than the second material.

The access devices can be coupled to the plurality of storage nodes 374. In some embodiments, the plurality of storage nodes 374 can be double-sided capacitors. The access devices can be used to transfer current between the metal material 372 and the plurality of storage nodes 374, which is a stack of multiple storage nodes, such as a stack of storage nodes 227 in FIG. 2.

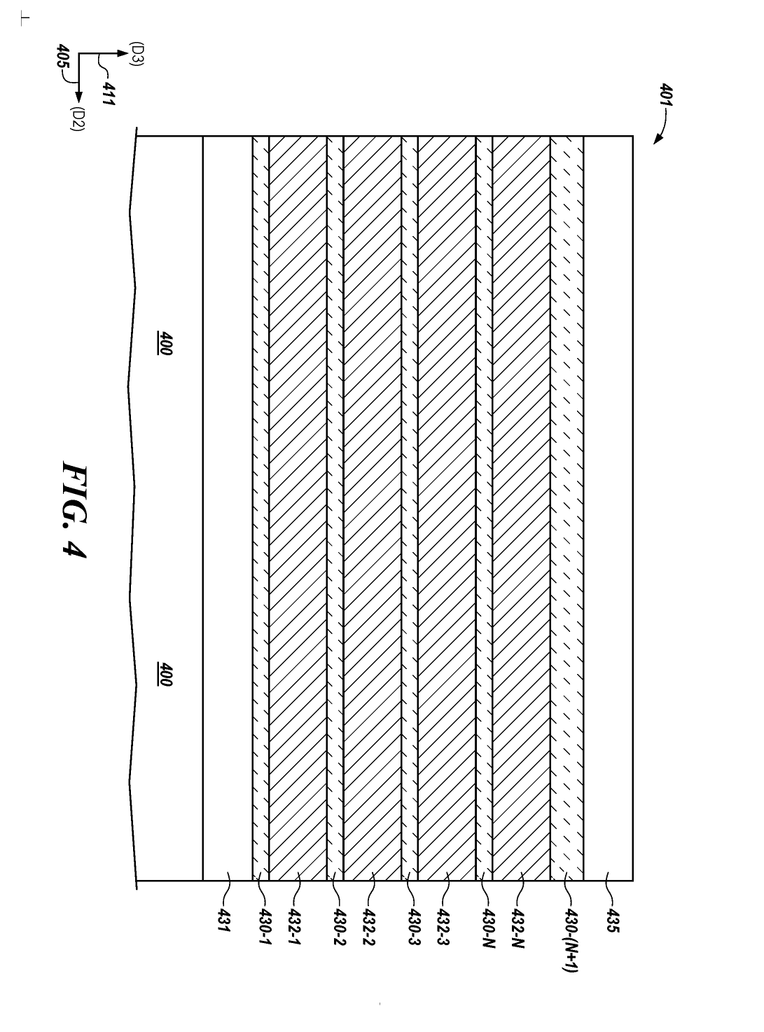

FIG. 4 is a cross-sectional view of a vertical stack in vertical three dimensional (3D) memory in accordance with a number of embodiments of the present disclosure. In the example embodiment shown in the example of FIG. 4, a method of forming the vertical stack 401 can comprise forming alternating layers of a silicon germanium (SiGe) material , 430-1, 430-2, . . ., 430-N (collectively referred to as silicon germanium (SiGe) 430), and a silicon (Si) material, 432-1, 432-2, . . ., 432-N (collectively referred to as single crystalline silicon (Si) material 432), in repeating iterations to form a vertical stack 401 on a working surface of a semiconductor substrate 400. In some embodiments, the silicon germanium (SiGe) material and the silicon (Si) material can be epitaxially grown.

In one embodiment, the silicon germanium (SiGe) 430 can be deposited to have a thickness (e.g., vertical height) in the third direction (D3), in a range of five (5) nanometers to thirty (30) nm. In one embodiment, the silicon (Si) material 432 can be deposited to have a thickness in a range of thirty (30) nanometers (nm) to sixty (60) nm. Embodiments, however, are not limited to these examples. As shown in FIG. 4, a vertical direction 411 is illustrated as a third direction (D3) (e.g., z-direction in an x-y-z coordinate system) analogous to the third direction (D3), among first, second, and third directions, shown in FIGS. 1-3.

In some embodiments, the silicon germanium (SiGe), 430-1, 430-2, . . ., 430-N, may be a mix of silicon and germanium. By way of example, and not by way of limitation, the silicon germanium (SiGe) material 430 may be grown on the substrate material 400. Embodiments are not limited to these examples. In some embodiments, the single crystalline silicon (Si) material, 432-1, 432-2, . . ., 432-N, may comprise a silicon (Si) material in a polycrystalline and/or amorphous state. The single crystalline silicon (Si) material, 432-1, 432-2, . . ., 432-N, may be a low doped, p-type (p-) single crystalline silicon (Si) material. The silicon (Si) material, 432-1, 432-2, . . ., 432-N, may also be formed on the silicon germanium (SiGe) 430. If the silicon germanium (SiGe) 430 was epitaxially grown, the seed can be turned to pure silicon after the silicon germanium (SiGe) 430 has been formed.

The repeating iterations of alternating silicon germanium (SiGe), 430-1, 430-2, . . ., 430-N layers and single crystalline silicon (Si) material, 432-1, 432-2, . . ., 432-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of silicon germanium (SiGe) and single crystalline silicon (Si) material, in repeating iterations to define the vertical stack 401.

The layers may occur in repeating iterations vertically. For example, the stack may include: a first silicon germanium (SiGe) material 430-1, a first single crystalline silicon (Si) material 432-1, a second silicon germanium (SiGe) material 430-2, a second single crystalline silicon (Si) material 432-2, a third silicon germanium (SiGe) material 430-3, and a third single crystalline silicon (Si) material 432-3, in further repeating iterations. Embodiments, however, are not limited to this example and more or fewer repeating iterations may be included.

In some embodiments, a bottom portion of the vertical stack 401 can be removed to form a horizontal opening. The bottom portion of the vertical stack 401 can include a layer of silicon germanium (SiGe) material 430 that is closer to the substrate 400 than other layers of silicon germanium (SiGe) material 430, a layer of silicon (Si) material 432 that is closer to the substrate 400 than other layers of silicon (Si) material 432, or both. Further, a dielectric material 431 can be deposited to fill the horizontal opening.

FIG. 5A illustrates an example method, at one stage of a semiconductor fabrication process, for forming an access line structure for a memory device, in accordance with a number of embodiments of the present disclosure. FIG. 5A illustrates a top down view of a semiconductor structure, at a particular point in time, in a semiconductor fabrication process, according to one or more embodiments. In the example embodiment shown in the example of FIG. 5A, the method comprises using an etchant process to form a plurality of vertical openings 515-1, 515-2, 515-3, . . ., 515-N (individually or collectively referred to as vertical openings 515), having a first horizontal direction (D1) 509 and a second horizontal direction (D2) 505, through the vertical stack to the substrate. In one example, as shown in FIG. 5A, the plurality of vertical openings 515 are extending predominantly in the second horizontal direction (D2) 505 and may define elongated vertical columns of the alternating layers 513-1, 513-2, . . ., 513-M (collectively and/or independently referred to as vertical, pillar columns 513), with sidewalls 514 in the vertical stack. The plurality of first vertical openings 515 may be formed using photolithographic techniques to pattern a photolithographic mask 535 (e.g., to form a hard mask (HM)), on the vertical stack prior to etching the plurality of first vertical openings 515. Similar semiconductor process techniques may be used at other points of the semiconductor fabrication process described herein.

The first vertical openings 515 may be filled with a first dielectric material 539. In one example, a spin on dielectric process may be used to fill the first vertical openings 515. In one embodiment, the first dielectric material 539 may be an oxide material. However, embodiments are not so limited.

In some embodiments, one of the plurality of first vertical openings (e.g., first vertical opening 515-1) can be formed to a second width in a first horizontal direction (D1) 509 that is different from a first width in the first horizontal direction (D1) 509 of other ones of the plurality of first vertical openings (e.g., first vertical openings 515-2, 515-3, . . ., 515-N). For example, as shown in FIG. 5A, the second width of the first horizontal opening 515-1 can be greater than the first width of other first horizontal openings 515-2, 515-3, . . ., 515-N. More specifically, the second width in the first horizontal direction (D1) 509 can be in a range of one and a half (1.5x) to twice (2x) a width of the first width.

In some embodiments, a photolithographic mask 535 can be used to pattern the one of the first vertical openings 515-1 to the second width that is greater than the first width of the plurality of other first vertical openings 515-2, 515-3, . . ., 515-N. Further, a first etch process can be used to form the first vertical openings 515-2, 515-3, . . ., 515-N having the first width in the first horizontal direction (D1) 509 and a second etch process can be used to form the first vertical opening 515-1 having the second width in the first horizontal direction (D1) 509. In some embodiments, the first etch process can be a wet etch process and the second etch process can be a dry etch process. As used herein, a “wet etch process” refers to an etching process that uses liquid chemicals to remove material from the vertical stack. As used herein, a “dry etch process” refers to an etching process that uses gaseous products to remove material from the vertical stack.

FIG. 5B is a cross sectional view, taken along cut-line A-A’ in FIG. 5A, showing another view of the semiconductor structure at a particular time in the semiconductor fabrication process for forming an access line structure for a memory device, in accordance with a number of embodiments of the present disclosure. The cross sectional view shown in FIG. 5B shows the repeating iterations of alternating layers of a silicon germanium (SiGe) material 530 and a single crystalline silicon (Si) material 532 on a semiconductor substrate 500 to define the vertical stack (e.g., vertical stack 501 in FIG. 5).

As shown in FIG. 5B, a plurality of vertical openings may be formed through the layers within the vertically stacked memory cells to expose vertical sidewalls in the vertical stack and define elongated vertical pillar columns (e.g., vertical pillar columns 513 in FIG. 5A) and then filled with a first dielectric material 539. The first vertical openings (e.g., first vertical openings 515 in FIG. 5A) may be formed through the repeating iterations of the silicon germanium (SiGe) material 530 and the single crystalline silicon (Si) material 532. As such, the first vertical openings may be formed through a first silicon germanium (SiGe) material 530-1, a first single crystalline silicon (Si) material 532-1, a second silicon germanium (SiGe) material 530-2, a second single crystalline silicon (Si) material 532-2, a third silicon germanium (SiGe) material 530-3, and a third single crystalline silicon (Si) material 532-3. Embodiments, however, are not limited to the vertical opening(s) shown in FIG. 5B. Multiple vertical openings may be formed through the layers of materials. The vertical openings may be formed to expose vertical sidewalls in the vertical stack. The vertical openings may extend in a second direction (D2) 505 to define elongated vertical columns of the alternating layers with vertical sidewalls in the vertical stack and then filled with first dielectric 539.

As shown in FIG. 5B, a first dielectric material 539, such as an oxide or other suitable spin on dielectric (SOD), may be deposited in the first vertical openings, using a process such as CVD, to fill the first vertical openings. First dielectric material 539 may also be formed from a silicon nitride (Si₃N₄) material. In another example, the first dielectric material 539 may include silicon oxy-nitride (SiOₓN_{y}), and/or combinations thereof. Embodiments are not limited to these examples. The plurality of first vertical openings may be formed using photolithographic techniques to pattern a photolithographic mask 535 (e.g., to form a hard mask (HM)) on the vertical stack prior to etching the plurality of first vertical openings. In one embodiment, hard mask 535 may be deposited over a silicon germanium (SiGe) material 530. Similar semiconductor process techniques may be used at other points of the semiconductor fabrication process described herein.

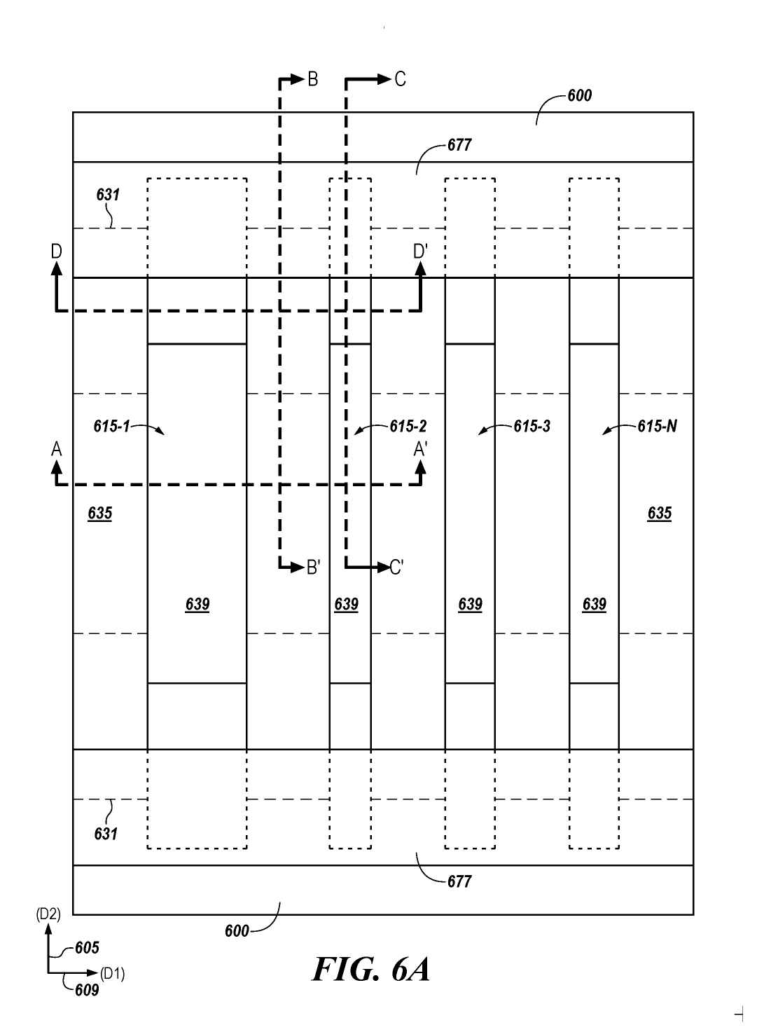

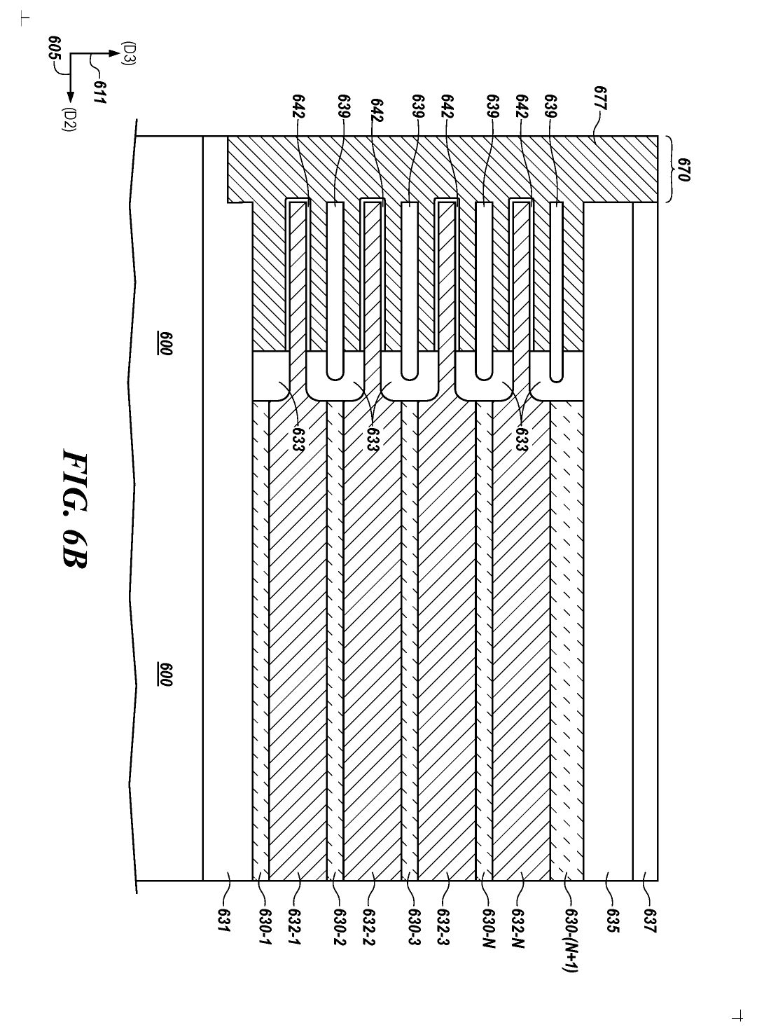

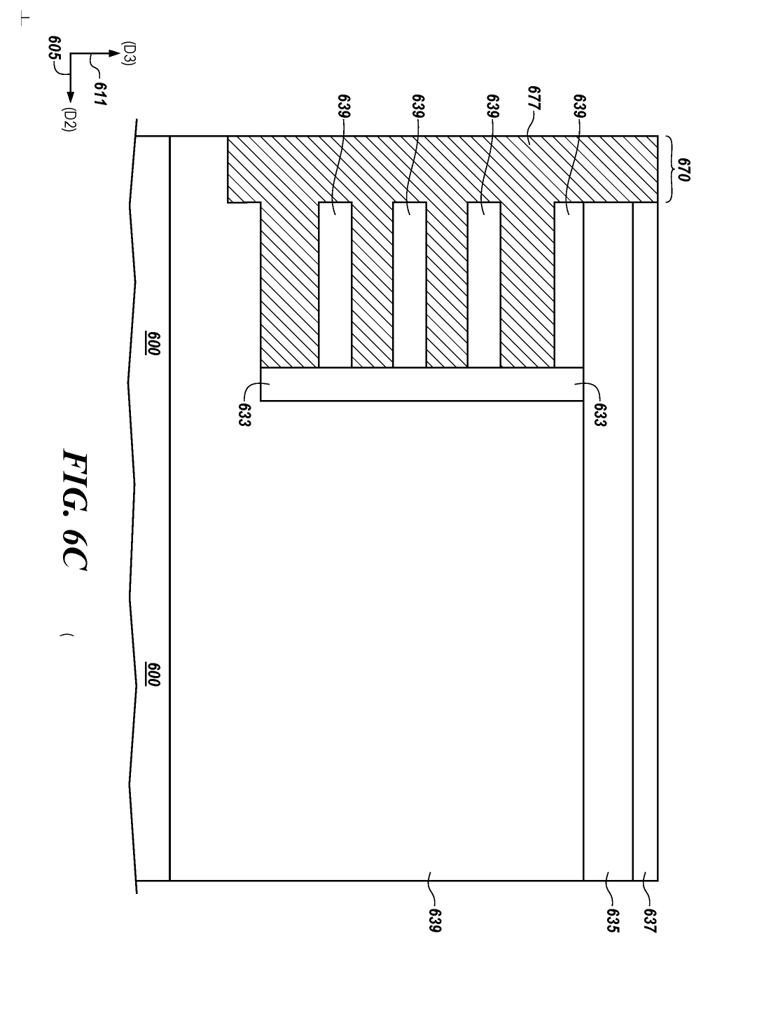

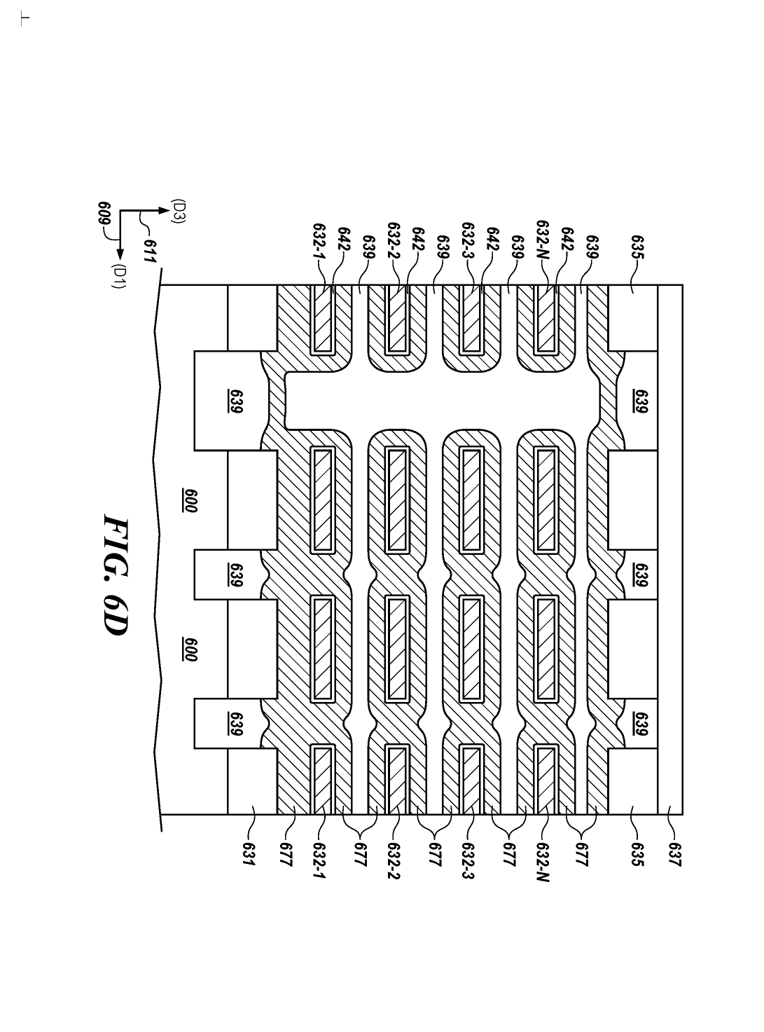

FIG. 6A illustrates an example method, at another stage of a semiconductor fabrication process for forming an access line structure for a memory device, in accordance with a number of embodiments of the present disclosure. FIG. 6A illustrates a top down view of a semiconductor structure, at a particular point in time, in a semiconductor fabrication process, according to one or more embodiments. In the example embodiment of FIG. 6A, the method comprises using a photolithographic process to pattern the photolithographic mask 635. A first conductive material 677 may be deposited above the vertical openings 631. The first conductive material 677 may be deposited in the continuous first horizontal openings to form horizontally oriented access lines opposing channel regions of the single crystalline silicon (Si) material 632. As shown in FIG. 6A, a width of a first vertical opening 615-1 can be greater than a width of other first vertical openings 315-2, 615-3, . . ., 615-N.

FIG. 6B illustrates a cross sectional view, taken along cut-line B-B’ in FIG. 6A, showing another view of the semiconductor structure at this particular point in one example semiconductor fabrication process for forming an access line structure for a memory device, in accordance with embodiments of the present disclosure. The cross sectional view shown in FIG. 6B is illustrated extending in the second horizontal direction (D2) 605, left and right along the plane of the drawing sheet, along an axis of the repeating iterations of alternating layers of the silicon germanium (SiGe) material 630 and the single crystalline silicon (Si) material 632.

A process of depositing and etching materials can be used to form the structure shown in FIG. 6B. In some embodiments, the process of depositing and etching materials can include forming horizontally oriented access devices and horizontally oriented storage nodes (e.g., storage nodes 227 in FIG. 2) at each level of the vertical stack (e.g., vertical stack 501 in FIG. 5) to form an array of vertically stacked memory cells. Each of the horizontally oriented access devices can have first source/drain regions and second source/drain regions separated by channel regions. In some embodiments, gates can be formed fully around every surface of the channel regions as gate all around (GAA) structures on a gate dielectric material. Further, in some embodiments, the second source/drain regions can be coupled to storage nodes.

The semiconductor structure shown in FIG. 6B shows the semiconductor structure after the silicon germanium (SiGe) layers are selectively etched to form a plurality of first horizontal openings a first length from first vertical openings 670. In some embodiments, the second vertical openings 670 can be formed to a depth in a range of 0.5 to one (1) micrometer (µm). Further, in some embodiments, each of the first vertical openings 670 can be formed to have an aspect ratio in a range of 15-20. In some embodiments, the selective etch that forms to plurality of second horizontal openings can also reduce a vertical thickness of the silicon (Si) layers. In some embodiments, a vertical thickness of a portion of each of the silicon (Si) layers can be reduced to a vertical thickness in a range of 100-150 Angstroms (Å).

The process of forming the horizontally oriented access devices can further include conformally depositing a second dielectric material 633 on exposed surfaces in the plurality of first horizontal openings and depositing the first dielectric material 639 to fill the plurality of first horizontal openings. The second dielectric material 633 can be selectively etched from the plurality of first horizontal openings a second length (L2) from the first vertical opening 670. In some embodiments, the second length (L2) can be a length in a range of 130-170 nanometers (nm).

A first conductive material 677 may be deposited in the first horizontal opening on the gate dielectric material 642 after selectively etching the second dielectric material 639. The first conductive material 677 may be deposited around the single crystalline silicon (Si) material 632 such that the first conductive material 677 may have a top portion above the single crystalline silicon (Si) material 632 and a bottom portion below the single crystalline silicon (Si) material to form a gate all around (GAA) gate structure, at a channel of an access device region. The first conductive material 677 may be conformally deposited into vertical openings 670 and fill the continuous horizontal openings up to the unetched portions of the oxide material 642, the first dielectric material 639, and the second dielectric material 633. The conductive material 677 may be conformally deposited using a chemical vapor deposition (CVD) process, plasma enhanced CVD (PECVD), atomic layer deposition (ALD), or other suitable deposition process.

In some embodiments, the first conductive material, 677, may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The first conductive material 677 entwined with the gate dielectric material may form horizontally oriented access lines opposing a channel region of the single crystalline silicon (Si) material (which also may be referred to as word lines).

FIG. 6C illustrates a cross sectional view, taken along cut-line C-C’ in FIG. 6A, showing another view of the semiconductor structure at this particular point in one ex ample semiconductor fabrication process for forming an access line structure for a memory device, in accordance with embodiments of the present disclosure. The cross sectional view shown in FIG. 6C is illustrated extending in the second horizontal direction (D2) 605, left and right in the plane of the drawing sheet, along an axis of the repeating iterations of alternating layers of continuous horizontal openings and single crystalline silicon (Si) material (e.g., silicon (Si) material 632 in FIG. 6B).

In FIG. 6C, first dielectric material 639 is shown spaced along a second horizontal direction (D2) 605, extending into and out from the plane of the drawings sheet, for a three dimensional (3D) array of vertically oriented memory cells. At the left end of the drawing sheet is shown the repeating iterations of alternating layers of single crystalline silicon (Si) material 632, separated by continuous horizontal openings in a first direction (D1) 609 filled with a first conductive material 677. The first conductive material 677 may be conformally deposited into vertical openings 670 and into the horizontal openings. The first conductive material 677 is formed on the gate dielectric material (e.g., gate dielectric material 642 in FIG. 6B). At the right hand of the drawing sheet, the first dielectric material 639 may be seen, separating access device and storage node regions in the first direction (D1) 609, and having the horizontal opening filled with the second dielectric material 633 and the first dielectric material 639.

FIG. 6D illustrates a cross sectional view, taken along cut-line D-D’ in FIG. 6A, showing another view of the semiconductor structure at this particular point in one example semiconductor fabrication process for forming an access line structure in a memory device, in accordance with a number of embodiments of the present disclosure. The cross sectional view shown in FIG. 6D is illustrated, right to left in the plane of the drawing sheet, extending in the first direction (D1) 609 along an axis of the repeating iterations of alternating layers of first dielectric material 639 and single crystalline silicon (Si) material 632 wrapped with a gate dielectric material 642. The gate dielectric material 642 may be conformally deposited fully around every surface of the single crystalline silicon (Si) material 632, to form gate all around (GAA) gate structures, at the channels of the access device regions. The first conductive material 677 may fill the spaces adjacent the bridged single crystalline silicon (Si) material 632. The single crystalline silicon (Si) material 632 may be surrounded by the first conductive material 677 formed on the gate dielectric material 642. The first conductive material 677 may be conformally deposited fully around every surface of the single crystalline silicon (Si) material 632, to form gate all around (GAA) gate structures, at the channels of the access device regions. In FIG. 6D, the first conductive material, 677 is shown filling in the space in the second horizontal openings left by the etched second dielectric material 633.

The first conductive material 677 can be separated in the left-most opening of FIG. 6D. The left-most opening can correspond to a first vertical opening (e.g., first vertical opening 615-1 in FIG. 6A) width a greater width than the width of other first vertical openings (e.g., first vertical openings 615-2, 615-3, . . ., 615-N). The increased width of the first vertical opening 615-1 can result in a gap between the iterations of silicon (Si) material 632, gate dielectric material 642, and first conductive material 677 on one side of the gap corresponding to the first vertical opening 615-1 and iterations of the silicon (Si) material 632, gate dielectric material 642 and first conductive material 677 on an opposite side of the gap.

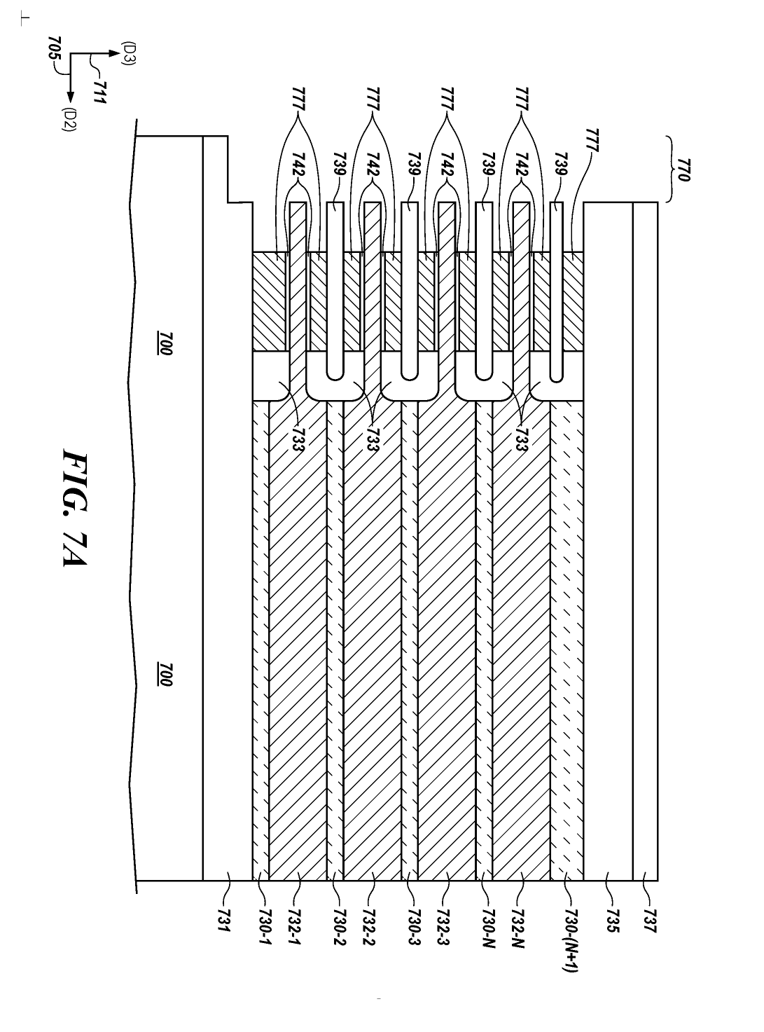

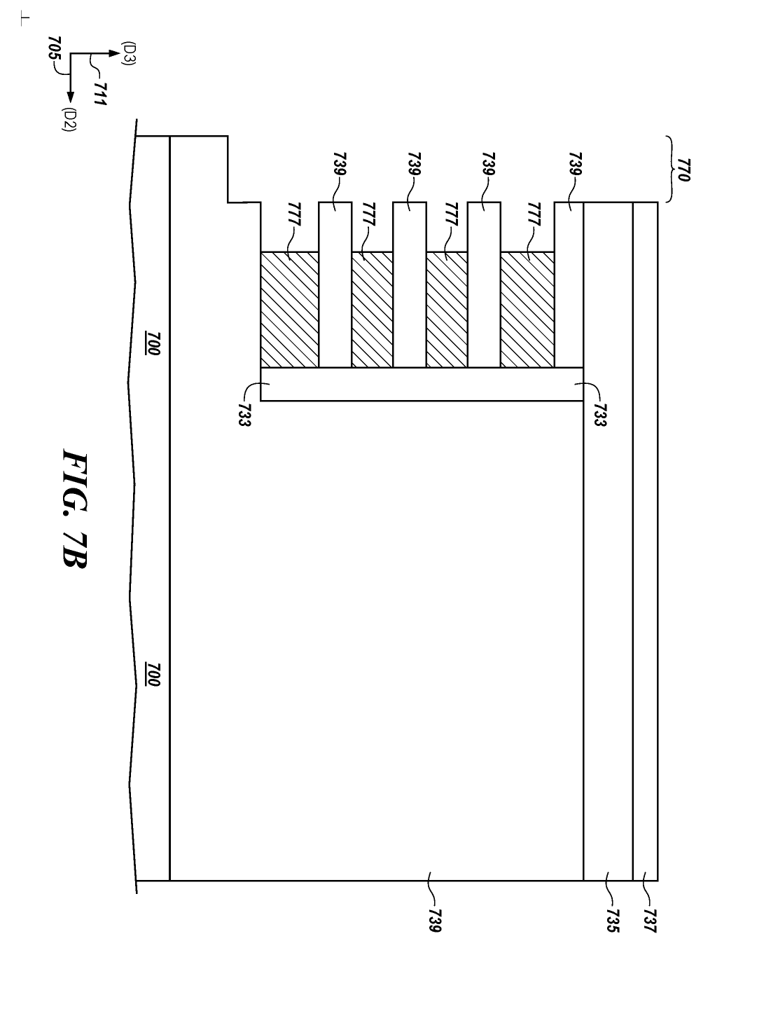

FIG. 7A illustrates an example method, at another stage of a semiconductor fabrication process, for forming an access line structure for a memory device, in accordance with a number of embodiments of the present disclosure. The cross sectional view shown in FIG. 7A is illustrated extending in the second horizontal direction (D2) 705, left and right along the plane of the drawing sheet, along an axis of the repeating iterations of alternating layers of the silicon germanium (SiGe) material 730 and the single crystalline silicon (Si) material 732.

A first conductive material 777 was deposited on the gate dielectric material and formed around the single crystalline silicon (Si) material 732, recessed back, to form a gate all around (GAA) structure opposing channel regions of the single crystalline silicon (Si) material 732. The first conductive material 777, formed on the gate dielectric material 742, may be recessed and etched away from the vertical opening 770. In some embodiments, the first conductive material 777 may be etched using an atomic layer etching (ALE) process. In some embodiments, the first conductive material 777 may be etched using an isotropic etch process. The first conductive material 777 may be selectively etched leaving the oxide material 742 covering the single crystalline silicon (Si) material 732 and the first dielectric material 739 intact. The first conductive material 777 may be selectively etched in the second direction, in the continuous horizontal openings, a third distance in a range of twenty (20) to fifty (50) nanometers (nm) back from the first vertical opening 770. The first conductive material 777 may be selectively etched around the single crystalline silicon (Si) material 732 back into the continuous horizontal openings extending in the first horizontal direction.

FIG. 7B illustrates an example method, at another stage of a semiconductor fabrication process, for forming an access line structure in a memory device, in accordance with a number of embodiments of the present disclosure. The cross sectional view shown in FIG. 7B is illustrated extending in the second direction (D2) 705, left and right in the plane of the drawing sheet, along an axis of the repeating iterations of alternating layers of the etched first conductive material 777 and single crystalline silicon (Si) material 732.

In FIG. 7B, first dielectric material 739 is shown spaced along a first horizontal direction (D1) 709 extending into and out from the plane of the drawings sheet, for a three dimensional (3D) array of vertically oriented memory cells. At the left end of the drawing sheet is shown the first conductive material 777 formed on the gate dielectric material 742, was etched away from the vertical opening 770. The first conductive material 777, formed on the gate dielectric material 742, is also recessed back in the continuous horizontal openings extending in the first horizontal direction 709. The first conductive material 777 may be selectively etched leaving the oxide material 742 covering the single crystalline silicon (Si) material 732 intact. In some embodiments, the first conductive material 777 may be etched using an atomic layer etching (ALE) process. In some embodiments, the first conductive material 777 may be etched using an isotropic etch process.

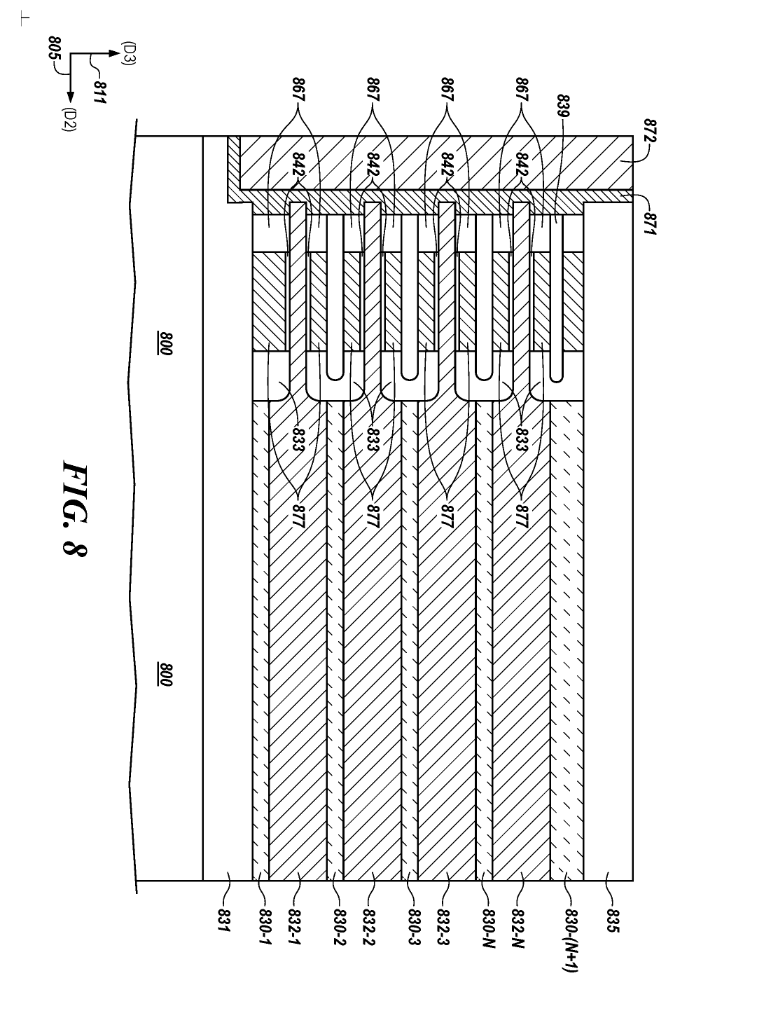

FIG. 8 illustrates an example method, at another stage of a semiconductor fabrication process, for forming an access line structure in memory device, in accordance with a number of embodiments of the present disclosure. The cross sectional view shown in FIG. 8 is illustrated extending in the second horizontal direction (D2) 805, left and right along the plane of the drawing sheet.

FIG. 8 illustrates an example embodiment of a vertical digit line formed by the combination of second conductive material 871 and third conductive material 872 formed within the first vertical openings (e.g., vertical openings 770 in FIG. 7). In one example, a second conductive material 871 may be conformally formed in the vertical openings. The second conductive material 871 may be formed from a conformal deposition of a highly doped polysilicon material 871. In one example, the dopant can include a high concentration n-type dopant. In a further example, the polysilicon may first be deposited and then a high concentration of n-type dopant may be implanted therein from the second conductive material 871. One example of forming the second conductive material 870 includes conformally depositing a highly phosphorus (P) doped (n+-type dopant) poly-silicon germanium (SiGe) material into the first vertical openings for the second conductive material 871.

A third conductive material 872 may be deposited into the first vertical opening on the second conductive material 871 to fill the vertical opening as shown in FIG. 8. In some embodiments, the third conductive material 872 may comprise one or more of a doped semiconductor material, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The third conductive material 872 coupled to the second conductive material 871 may be formed vertically adjacent first source/drain regions to horizontal access devices to form vertical digit lines.

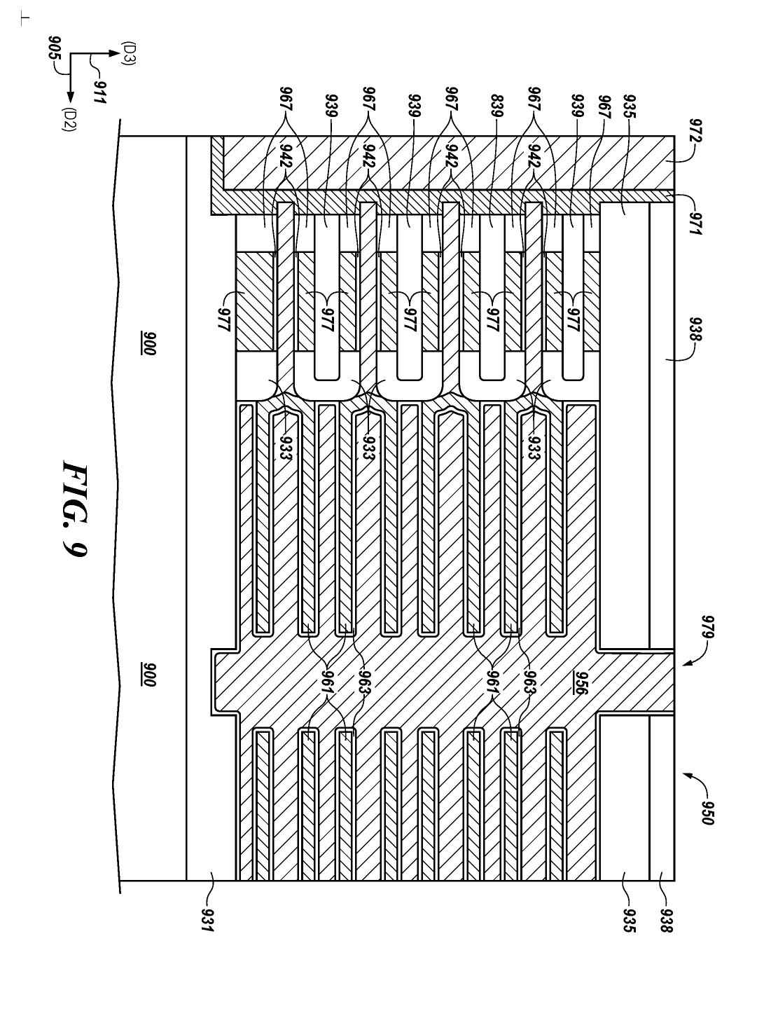

FIG. 9 illustrates an example method at another stage of a semiconductor fabrication process for forming an access line structure for a memory device, in accordance with a number of embodiments of the present disclosure. The cross sectional view shown in FIG. 9 is illustrated extending in the second horizontal direction (D2) 905, left and right along the plane of the drawing sheet, along the axis of repeating iterations of alternating layers of second electrodes 956 in which the horizontally oriented access devices and horizontally oriented storage nodes, e.g., capacitor cells, can be formed within the layers of silicon (Si) material.

In the example embodiment of FIG. 9, the horizontally oriented storage nodes (e.g., capacitor cells) are illustrated as having been formed in this semiconductor fabrication process and first electrodes 961 (e.g., bottom electrodes) to be coupled to source/drain regions of horizontal access devices, and second electrodes 956 (e.g., top electrodes) to be coupled to a common electrode plane such as a ground plane, separated by cell dielectrics 963, are shown. In this embodiment, a dual-sided capacitor is illustrated as an alternative to the single-sided capacitor. However, embodiments are not limited to this example. In other embodiments, the first electrodes 961 (e.g., bottom electrodes) to be coupled to source/drain regions of horizontal access devices, and second electrodes 956 (e.g., top electrodes) to be coupled to a common electrode plane such as a ground plane, separated by cell dielectrics 963, may be formed subsequent to forming a first source/drain region, a channel region, and a second source/drain region in a region of the epitaxially grown, single crystalline silicon (Si) material 932, intended for location (e.g., placement formation) of the horizontally oriented access devices.

In the example embodiment of FIG. 9, the horizontally oriented storage nodes having the first electrodes 961 (e.g., bottom electrodes) to be coupled to source/drain regions of horizontal access devices, and second electrodes 956 (e.g., top electrodes) to be coupled to a common electrode plane such as a ground plane, are shown formed in a horizontal opening, extending in second direction 905, left and right in the plane of the drawing sheet, a distance from the vertical opening formed in the vertical stack, and along an axis of orientation of the horizontal access devices and horizontal storage nodes of the arrays of vertically stacked memory cells of the three dimensional (3D) memory.

In FIG. 9, a neighboring, horizontal access line 977 is illustrated adjacent the second dielectric material 933, with a portion of the first conductive material 977 located above the silicon (Si) material 932, and a portion of the first conductive material 977 located below the silicon (Si) material 932 indicating a location set inward from the plane and orientation of the drawing sheet. The first and the second source/drain regions may be formed by gas phase doping a dopant in a side surface of the silicon (Si) material 932 from the horizontal openings to form second source/drain regions horizontally adjacent the channel region; and depositing horizontally oriented capacitor cells having a bottom electrode formed in electrical contact with the second source/drain regions.

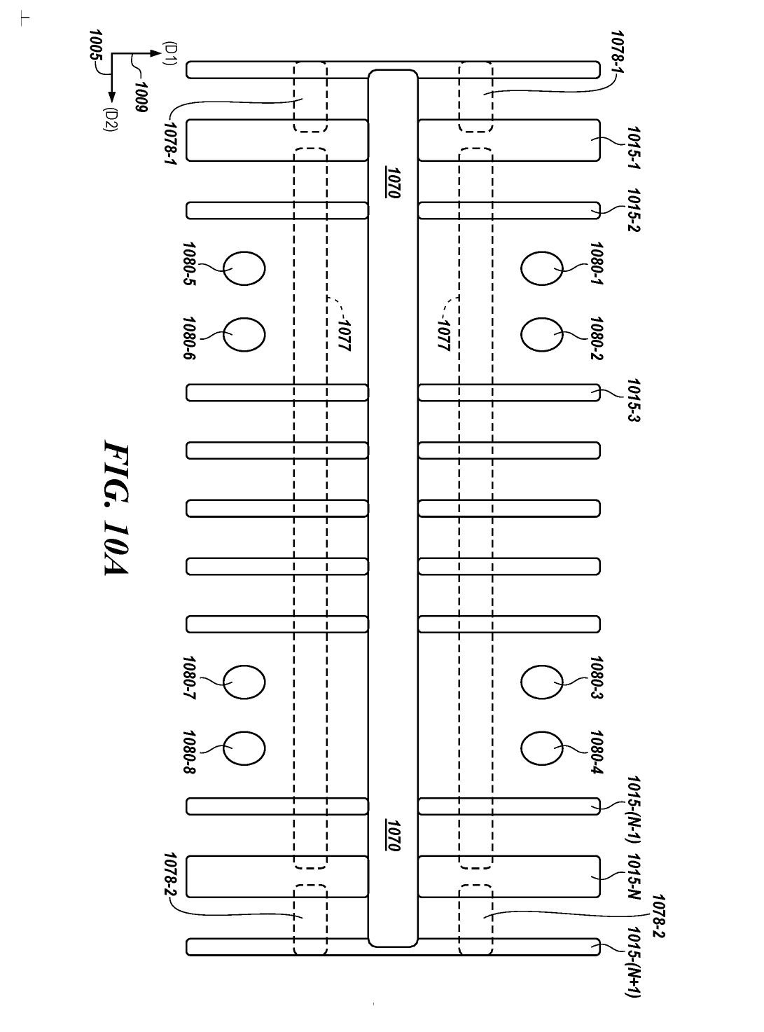

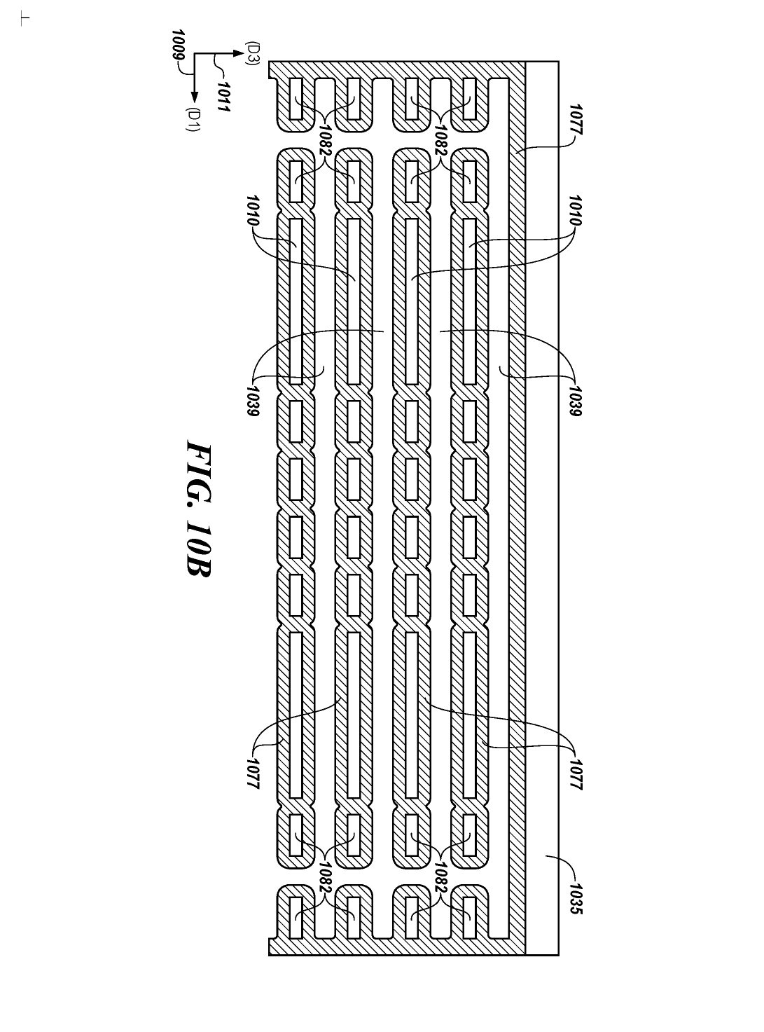

FIG. 10A illustrates a top-down view of an access line structure in a memory device, in accordance with a number of embodiments of the present disclosure. FIG. 10A includes a plurality of first vertical openings 1015-1, 1015-2, 1015-3, . . ., 1015-N (individually or collectively referred to as first vertical openings 1015), a second vertical opening 1070, access line contacts 1080-1, 1080-2, 1080-3, 1080-4, 1080-5, 1080-6, 1080-7, 1080-8 (individually or collectively referred to as access line contacts 1080), active access line 1077, and redundant access lines 1078-1, 1078-2 (individually or collectively referred to as redundant access lines 1078).

As shown in FIG. 10A, the width of first vertical opening 1015-1 can be greater than the width of vertical opening 1015-2. In some embodiments, the width of first vertical opening 1015-1 can be in a range of one and a half (1.5x) to twice (2x) the width of the first vertical opening 1015-2. Due to the greater width of the first vertical opening 1015-1, a horizontally oriented redundant access line 1078-1 on one side of the first vertical opening 1015-1 may not couple to a horizontally oriented active access line 1077 on an opposite side of the first vertical opening 1015-1. The horizontally oriented redundant access line 1078-1 may not couple to the horizontally oriented active access line 1077 at a location corresponding to the first vertical opening 1015-1 because the conductive material (e.g., conductive material 977 in FIG. 9) cannot cascade across the increased width of the first vertical opening 1015-1 when the conductive material is deposited. Therefore, the horizontally oriented access line formed from the conductive material cannot be formed continuously across the first vertical opening 1015-1.

In some embodiments, vertical opening 1015-1 can be in a location corresponding to a first side of the active access line 1077 and the vertical opening 1015-2 can be in a location between the first side of the active access line 1077 and a second side of the respective access line 1077. Further, in some embodiments, the first side of the active access line 1077 can be an opposite side of the active access line 1077 than the second side of the active access line 1077. The vertical opening 1015-(N) can have the second width and can be in a location corresponding to the second side of the active access line 1077. In some embodiments, one or more second, first vertical openings 1015-2, 1015-3, . . ., 1015-(N-1) can be located between the first, first vertical opening 1015-1 and the third, first vertical opening 1015-(N).

In some embodiments, the first vertical opening 1015-1 can be formed between a first portion of the vertical stack and a second portion of the vertical stack. In some embodiments, the first portion of the vertical stack can be a main portion of the vertical stack and the second portion of the vertical stack can be a periphery of the vertical stack. As used herein, the term “main portion” of the vertical stack refers to an area between the edges of the vertical stack and can include active memory cells of the vertical stack. As used herein, the term “periphery” of the vertical stack refers to an area at an edge of the vertical stack. For example, the periphery of the vertical stack can refer to the portion of the vertical stack that includes an area of a structure within the vertical stack that is adjacent a vertical opening that separates a main portion of the vertical stack from a periphery of the vertical stack. In some embodiments, a periphery of a vertical stack can include, but is not limited to, a staircase structure.

In some embodiments, the first portion of the vertical stack can include an active access line and the second portion of the vertical stack can include a redundant access line. Further, in some embodiments, the one of the plurality of first vertical openings (e.g., first vertical opening 1015-1) can disconnect the active access line 1077 from a redundant access line 1078-1.

FIG. 10B illustrates a side view of an array of memory cells below an access line structure in a memory device, in accordance with a number of embodiments of the present disclosure. FIG. 10B includes active memory cells 1010, redundant memory cells 1082, horizontally oriented active access lines 1077, first dielectric material 1039, and mask material 1035.

In some embodiments, the active memory cells 1010 can be memory cells coupled to an active access line (e.g., active access line 1077 in FIG. 10A) and redundant memory cells 1082 can refer to memory cells coupled to a redundant access line (e.g., redundant access lines 1078 in FIG. 10A). As shown in FIG. 10B, active memory cells 1010 can be decoupled from redundant memory cells 1082 at locations corresponding to first, first vertical openings that have a second width and/or third, first vertical openings having the second width. This separation of active memory cells 1010 and redundant memory cells 1082 can allow the active memory cells 1010 to be activated without unintentionally activating redundant memory cells 1082.

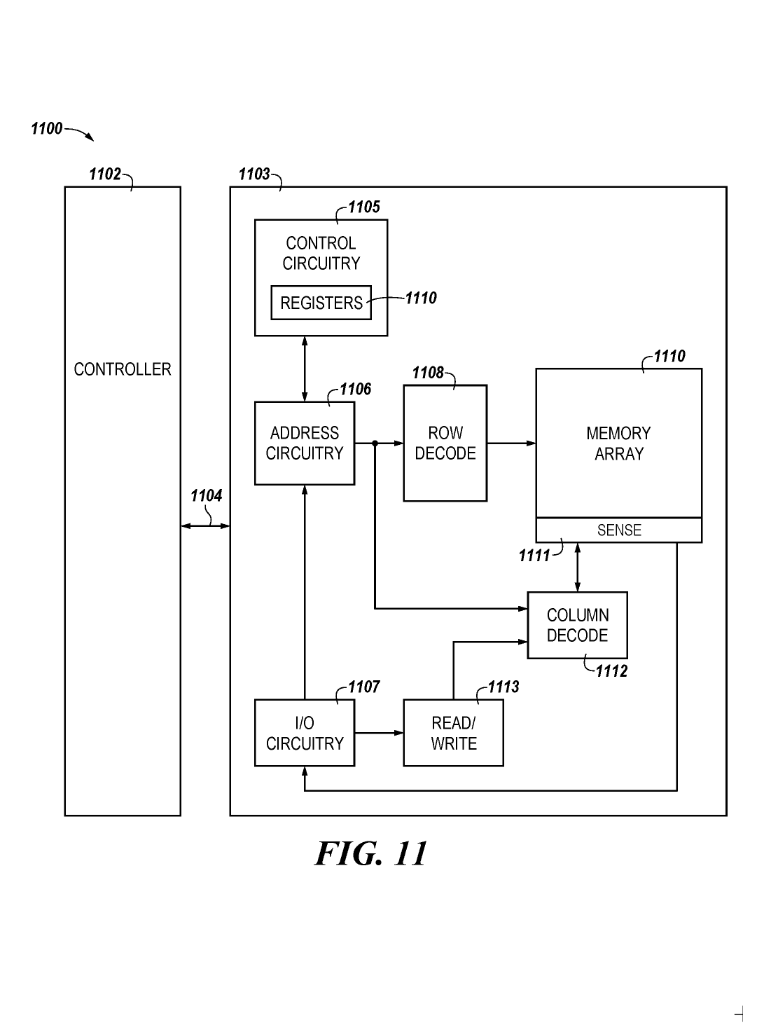

FIG. 11 is a block diagram of an apparatus in the form of a computing system 1100 including a memory device 1103 in accordance with a number of embodiments of the present disclosure. As used herein, a memory device 1103, a memory array 1110, and/or a host 1102, for example, might also be separately considered an “apparatus.” According to embodiments, the memory device 1103 may comprise at least one memory array 1110 with a memory cell formed having a digit line and body contact, according to the embodiments described herein.

In this example, system 1100 includes a host 1102 coupled to memory device 1103 via an interface 1104. The computing system 1100 can be a personal laptop computer, a desktop computer, a digital camera, a mobile telephone, a memory card reader, or an Internet-of-Things (IoT) enabled device, among various other types of systems. Host 1102 can include a number of processing resources (e.g., one or more processors, microprocessors, or some other type of controlling circuitry) capable of accessing memory 1103. The system 1100 can include separate integrated circuits, or both the host 1102 and the memory device 1103 can be on the same integrated circuit. For example, the host 1102 may be a system controller of a memory system comprising multiple memory devices 1103, with the system controller 1105 providing access to the respective memory devices 1103 by another processing resource such as a central processing unit (CPU).

In the example shown in FIG. 11, the host 1102 is responsible for executing an operating system (OS) and/or various applications (e.g., processes) that can be loaded thereto (e.g., from memory device 1103 via controller 1105). The OS and/or various applications can be loaded from the memory device 1103 by providing access commands from the host 1102 to the memory device 1103 to access the data comprising the OS and/or the various applications. The host 1102 can also access data utilized by the OS and/or various applications by providing access commands to the memory device 1103 to retrieve said data utilized in the execution of the OS and/or the various applications.

For clarity, the system 1100 has been simplified to focus on features with particular relevance to the present disclosure. The memory array 1110 can be a DRAM array comprising at least one memory cell having a digit line and body contact formed according to the techniques described herein. For example, the memory array 1110 can be an unshielded DL 4F2 array such as a 3D-DRAM memory array. The array 1110 can comprise memory cells arranged in rows coupled by word lines (which may be referred to herein as access lines or select lines) and columns coupled by digit lines (which may be referred to herein as sense lines or data lines). Although a single array 1110 is shown in FIG. 11, embodiments are not so limited. For instance, memory device 1103 may include a number of arrays 1110 (e.g., a number of banks of DRAM cells).

The memory device 1103 includes address circuitry 1106 to latch address signals provided over an interface 1104. The interface can include, for example, a physical interface employing a suitable protocol (e.g., a data bus, an address bus, and a command bus, or a combined data/address/command bus). Such protocol may be custom or proprietary, or the interface 1104 may employ a standardized protocol, such as Peripheral Component Interconnect Express (PCIe), Gen-Z, CCIX, or the like. Address signals are received and decoded by a row decoder 1108 and a column decoder 1112 to access the memory array 1110. Data can be read from memory array 1110 by sensing voltage and/or current changes on the sense lines using sensing circuitry 1111. The sensing circuitry 1111 can comprise, for example, sense amplifiers that can read and latch a page (e.g., row) of data from the memory array 1110. The I/O circuitry 1107 can be used for bi-directional data communication with the host 1102 over the interface 1104. The read/write circuitry 1113 is used to write data to the memory array 1110 or read data from the memory array 1110. As an example, the circuitry 1113 can comprise various drivers, latch circuitry, etc.

Control circuitry 1105 decodes signals provided by the host 1102. The signals can be commands provided by the host 1102. These signals can include chip enable signals, write enable signals, and address latch signals that are used to control operations performed on the memory array 1110, including data read operations, data write operations, and data erase operations. In various embodiments, the control circuitry 1105 is responsible for executing instructions from the host 1102. The control circuitry 1105 can comprise a state machine, a sequencer, and/or some other type of control circuitry, which may be implemented in the form of hardware, firmware, or software, or any combination of the three. In some examples, the host 1102 can be a controller external to the memory device 1103. For example, the host 1102 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method for forming arrays of vertically stacked memory cells, having horizontally oriented access devices and storage nodes, comprising:
forming a vertical stack comprising alternating layers of silicon germanium (SiGe) material and silicon (Si) material;
forming a plurality of first vertical openings, having a first horizontal direction and a second horizontal direction, through the vertical stack, the first vertical openings extending predominantly in the second horizontal direction to define elongated vertical columns of the alternating layers with first vertical sidewalls in the vertical stack;
wherein one of the plurality of first vertical openings is formed having a second width (W2) in the first horizontal direction different from other ones of the plurality of first vertical openings having a first width (W1) in the first horizontal direction;
filling the plurality of first width (W1) and the second width (W2) vertical openings with a first dielectric material;
forming a second vertical opening through the vertical stack and extending predominantly in the first horizontal direction to expose second vertical sidewalls in the vertical stack;
selectively removing the silicon germanium (SiGe) layers and reducing a vertical thickness (H1) of the silicon (Si) layers, wherein selectively removing the silicon germanium (SiGe) layers removes the first dielectric material in the first width (W1) vertical openings along the first horizontal direction to define a plurality of continuous first horizontal openings having a first length (L1) from the second vertical opening; and
forming access lines in the first horizontal openings and separated from exposed surfaces of the Si layers by a gate dielectric at channels of horizontal access devices in an array portion of memory cells but separated from a peripheral portion of the array of memory cells by the first dielectric material in the second width (W2) vertical openings.

2. The method of claim 1, further comprising forming the second width in the first horizontal direction to be greater than the first width.

3. The method of claim 1, further comprising forming the second width to have a width in the first horizontal direction in a range of one and a half (1.5x) to twice (2x) a width of the first width.

4. The method of claim 1, further comprising using a photolithographic mask to pattern the one of the first vertical openings to the second width (W2) that is greater than the first width (W1) in the plurality of first vertical openings.

5. The method of claim 1, further comprising:
using a first etch process to remove alternating layers the first width (W1) in size in the first horizontal direction; and
using a second etch process to remove alternating layers the second width (W2) in size in the first horizontal direction.

6. The method of claim 5, further comprising:
using a wet etch process as the first etch process; and
using a dry etch process as the second etch process.

7. The method of claim 1, wherein forming the access lines in the first horizontal openings includes depositing a first conductive material that creates a continuous conductive path in and along a length of the first horizontal openings and is deposited to form gate all around (GAA) structures at channels of the horizontal access devices.

8. The method of claim 1, further comprising:
conformally depositing a second dielectric material on exposed surfaces of the Si material in the plurality of first horizontal openings;
filling the plurality of first horizontal openings with the first dielectric material;
selectively etching the second dielectric material from the plurality of first horizontal openings a second length (L2) from the second vertical opening;
depositing a gate dielectric on exposed surfaces of the Si material;
depositing a first conductive material on the gate dielectric in the first horizontal opening to form the access lines;
recessing the first conductive material in the first horizontal openings a third length (L3) from the second vertical opening; and
depositing the second dielectric material in a remaining portion of the first horizontal opening.

9. A method for forming arrays of vertically stacked memory cells, having horizontally oriented access devices and storage nodes, comprising:
forming alternating layers of a first semiconductor material and a second semiconductor material to define a plurality of levels in a vertical stack;
forming a plurality of first vertical openings, having a first horizontal direction and a second horizontal direction, through the vertical stack, the first vertical openings extending predominantly in the second horizontal direction to form elongated vertical columns of the alternating layers with first vertical sidewalls in the vertical stack;
wherein one of the plurality of first vertical openings is formed having a second width (W2) in the first horizontal direction that is different from other ones of the plurality of first vertical openings having a first width (W1) in the first direction;
filling the plurality of first vertical openings with a first dielectric material;
forming a second vertical opening through the vertical stack and extending predominantly in the first horizontal direction to expose second vertical sidewalls in the vertical stack;
selectively etching the first semiconductor material layers and reducing a vertical thickness (H1) of the second semiconductor material layers, wherein selectively etching the first semiconductor material layers removes the first dielectric material in the first width (W1) vertical openings along the first horizontal direction to form a plurality of continuous first horizontal openings up to the first dielectric material filled in the second width (W2) vertical openings, the first horizontal openings having formed a first distance (dist1) from the second vertical opening;
forming access lines in the plurality of continuous first horizontal openings and separated from exposed surfaces of the second semiconductor material layers by a gate dielectric at channel regions of horizontal access devices in an array portion of memory cells but separated from a redundant portion of the array of memory cells by the first dielectric material in the second width (W2) vertical openings.

10. The method of claim 9, further comprising forming the one of the plurality of first vertical openings having the second width (W2) between a main array portion of the vertical stack and a redundant array portion of the vertical stack.

11. The method of claim 10, wherein selectively etching forms a plurality of continuous second horizontal openings up to the first dielectric material filled in the second width (W2) vertical openings in the redundant array.

12. The method of claim 11, further comprising forming access lines in the plurality of continuous second horizontal openings in the redundant array concurrent with forming access lines in the main array to the redundant array portion of the vertical stack.

13. The method of claim 12, further comprising forming access lines in the main array and the redundant array separated by the second width (W2) vertical openings.

14. A memory device, comprising:
an array of vertically stacked memory cells, having a plurality of levels, each level of the array having horizontally oriented access devices and horizontally oriented storage nodes, comprising:
the horizontally oriented access devices having first source/drain regions and second source/drain regions separated by channels; and
the horizontally oriented storage nodes electrically connected to the second source/drain regions of the horizontally oriented access devices;
a plurality of first continuous access lines formed across a plurality of first isolation regions having a first width (W1), the first isolation regions separating the horizontal access devices on each level, the continuous access lines serving as gate all around (GAA) structures at the channels on each level;
a second isolation region having a second width (W2) separating a plurality second continuous access lines on each level in a redundant array of vertically stacked memory cells adjacent the array from the plurality of first continuous access lines, the second continuous access lines formed concurrently with the plurality of first continuous access lines.

15. The memory device of claim 14, wherein the plurality of first isolation regions having a first width (W1) on each level and the second isolation region having a second width (W2) on each level, the second width (W2) being greater than the first width (W1).

16. The memory device of claim 15, wherein the plurality of first isolation regions is formed concurrently with the second isolation region.

17. The memory device of claim 15, wherein the redundant array of vertically stacked memory cells adjacent the array is formed concurrently with the array and comprises a plurality of levels, each level of the redundant array of vertically stacked memory cells having horizontally oriented access devices and horizontally oriented storage nodes, each memory cell comprising:
a horizontally oriented access device having first source/drain regions and second source/drain regions separated by channels; and
a horizontally oriented storage node electrically connected to the second source/drain regions of the horizontally oriented access device.

18. The memory device of claim 17, wherein the plurality of first isolation regions and the second isolation region extend equally, vertically through each level of the array of vertically stacked memory cells and the redundant array of vertically stacked memory cells.

19. The memory device of claim 18, wherein the array of vertically stacked memory cells and the redundant array of vertically stacked memory cells includes at least eight (8) levels.

20. The memory device of claim 19, wherein each level of the array of vertically stacked memory cells and the redundant array of vertically stacked memory cells has a vertical height (H2) of less than one hundred nanometers (nm).
